(19) United States
(12) Patent Application Publication
(10) Pub. No.: US 2022/0077655 A1
(43) Pub. Date: Mar. 10, 2022

(54) SURFACE-EMITTING SEMICONDUCTOR LASER

(71) Applicant: SUMITOMO ELECTRIC INDUSTRIES, LTD., Osaka (JP)

(72) Inventor: Yuji KOYAMA, Osaka-shi (JP)

(73) Assignee: SUMITOMO ELECTRIC INDUSTRIES, LTD., Osaka (JP)

(21) Appl. No.: 17/376,943

(22) Filed: Jul. 15, 2021

(30) Foreign Application Priority Data
Sep. 4, 2020 (JP) 2020-148911

(51) Int. Cl. H01S 5/183; H01S 5/042

(52) U.S. Cl. CPC H01S 5/18347; H01S 5/04256

(57) ABSTRACT

A surface-emitting semiconductor laser includes a first conductive type semiconductor layer, a major mesa, a first sub-mesa, and a second sub-mesa. The first conductive type semiconductor layer has a portion on a first region and a portion on a third region that are separated from each other. The major mesa includes a first semiconductor laminate provided over the first region and on the first conductive type semiconductor layer, an active layer, a second semiconductor laminate, and a second conductive type semiconductor layer. The first sub-mesa is provided over the second region and on the first conductive type semiconductor layer. The second sub-mesa portion is provided over the third region and on the first conductive type semiconductor layer. The first bump is provided on the first pad electrode over the first sub-mesa. The second bump is provided on the second pad electrode over the second sub-mesa.

### CROSS REFERENCE TO RELATED APPLICATIONS

This application claims priority based on Japanese Patent Application No. 2020-148911 filed on Sep. 4, 2020, and the entire contents of the Japanese patent application are incorporated herein by reference.

### TECHNICAL FIELD

The present disclosure relates to a surface-emitting semiconductor laser.

### BACKGROUND

Patent Document 1 (Japanese Unexamined Patent Application Publication No. 2005-333018) discloses a technique related to an optical component suitably used in optical communication systems. The optical component includes an optical element having a protrusion made of a transparent resin on a light emitting portion or a light receiving portion, a transparent resin film on which the optical element is placed so that the protrusion of the optical element abuts, and a fixing means for fixing the optical element and the transparent resin film so that the protrusion presses the transparent resin film.

Patent Document 2 (Japanese Unexamined Patent Application Publication No. 2008-53423) discloses a technique related to a connector mounted by face-down bonding. This connector is a connector for connecting an optical element that has a first electrode formed on one surface thereof and a substrate that has a second electrode formed on one surface thereof to connect to the first electrode of the optical element. The second electrode has a recess and is connected to the first electrode through a bonding material. The optical element is a surface emitting element or a surface receiving element. The bonding material is a conductive bump or a solder.

Patent Document 3 (Japanese Unexamined Patent Application Publication No. 2009-21430) discloses a technique related to a surface-type optical element. The surface-type optical element includes a substrate, a light emitting/receiving portion, and an infiltration inhibiting region formed around the light emitting/receiving portion. The light emitting/receiving portion includes at least one of a light emitting portion for outputting light in a direction perpendicular to the substrate and a light receiving portion for inputting light in the same direction. The infiltration inhibiting region has a wettability inferior to that of an exposed portion around the light emitting/receiving portion to prevent an under-fill resin from entering the light emitting/receiving portion. The infiltration inhibiting region is provided in an annular shape around the light emitting/receiving portion.

### SUMMARY

A surface-emitting semiconductor laser according to a first aspect of the present disclosure includes a substrate, a first conductive type semiconductor layer, a major mesa, a first sub-mesa, a second sub-mesa, an insulating film, a first electrode, a second electrode, a first conductor, a second conductor, a first bump, and a second bump. The substrate has a principal surface including a first region, a second region, and a third region. The first conductive type semiconductor layer is provided on the principal surface, and a portion on the first region and a portion on the third region are separated from each other. The major mesa includes a first semiconductor laminate that is provided over the first region of the substrate and on the first conductive type semiconductor layer and that serves as a distributed Bragg reflector, an active layer provided on the first semiconductor laminate, a second semiconductor laminate that is provided on the active layer and that serves as a distributed Bragg reflector, and a second conductive type semiconductor layer provided on the second semiconductor laminate. The first sub-mesa is provided over the second region of the substrate and on the first conductive type semiconductor layer. The second sub-mesa portion is provided over the third region of the substrate and on the first conductive type semiconductor layer. The insulating film has a first opening provided over the first conductive type semiconductor layer connected to the main mesa and a second opening provided over a second conductive type semiconductor layer of the major mesa, and is provided on a side surface and an upper surface of each of the major mesa, the first sub-mesa, and the second sub-mesa. The first electrode is in contact with the first conductive type semiconductor layer through the first opening of the insulating film. The second electrode is in contact with the second conductive type semiconductor layer through the second opening of the insulating film. The first conductor includes a first pad electrode provided over the first sub-mesa and on the insulating film, and is electrically connected to the first electrode. The second conductor includes a second pad electrode provided over the second sub-mesa and on the insulating film, and extends on the insulating film along each side surface of the second sub-mesa and the major mesa to reach the second electrode. The first bump is provided on the first pad electrode. The second bump is provided on the second pad electrode.

A surface-emitting semiconductor laser according to a second aspect of the present disclosure includes a substrate, a first conductive type semiconductor layer, a major mesa, a first sub-mesa, a second sub-mesa, an insulating film, a first electrode, a second electrode, a first conductor, a second conductor, a first bump, and a second bump. The substrate has a principal surface including a first region, a second region, and a third region. The first conductive type semiconductor layer is provided on a region including at least the first region among other regions excluding the third region on the principal surface. The major mesa includes a first semiconductor laminate that is provided over the first region of the substrate and on the first conductive type semiconductor layer and that serves as a distributed Bragg reflector, an active layer provided on the first semiconductor laminate, a second semiconductor laminate that is provided on the active layer and that serves as a distributed Bragg reflector, and a second conductive type semiconductor layer provided on the second semiconductor laminate. The first sub-mesa includes a dielectric and is provided over the second region of the substrate. The second sub-mesa includes a dielectric and is provided over the third region of the substrate. The insulating film has a first opening provided over the first conductive type semiconductor layer and a second opening provided over the second conductive type semiconductor layer, and is provided on at least an upper surface and a side surface of the major mesa. The first electrode is in contact with the first conductive type semiconductor layer through the first opening of the insulating film. The second electrode is in contact with the second conductivity-type semiconductor layer through the second opening of the insulating film. The first conductor includes a first pad electrode provided over the first sub-mesa and is electrically connected to the first electrode. The second conductor includes a second pad electrode provided over the second sub-mesa. The second conductor extends along a side surface of the second sub-mesa and extends on the insulating film along a side surface of the major mesa to reach the second electrode. The first bump is provided on the first pad electrode. The second bump is provided on the second pad electrode.

### BRIEF DESCRIPTION OF THE DRAWINGS

The foregoing and other purposes, aspects and advantages will be better understood from the following detailed description of a preferred embodiment of the invention with reference to the drawings.

FIG. 1 is a plan view illustrating a surface-emitting semiconductor laser according to a first embodiment of the present disclosure.

FIG. 2 is a cross-sectional view taken along line II-II shown in FIG. 1.

FIG. 3 is a plan view illustrating a principal surface.

FIG. 4 is a cross-sectional view illustrating a step in an example of a method of manufacturing a semiconductor laser.

FIG. 5 is a cross-sectional view illustrating a step in an example of a method of manufacturing a semiconductor laser.

FIG. 6 is a cross-sectional view illustrating a step in an example of a method of manufacturing a semiconductor laser.

FIG. 7 is a cross-sectional view illustrating a step in an example of a method of manufacturing a semiconductor laser.

FIG. 8 is a cross-sectional view illustrating a step in an example of a method of manufacturing a semiconductor laser.

FIG. 9 is a cross-sectional view illustrating a step in an example of a method of manufacturing a semiconductor laser.

FIG. 10 is a cross-sectional view illustrating a step in an example of a method of manufacturing a semiconductor laser.

FIG. 11 is a cross-sectional view illustrating a step in an example of a method of manufacturing a semiconductor laser.

FIG. 12 is a plan view illustrating a semiconductor laser according to a modification of the first embodiment.

FIG. 13 is a plan view illustrating a semiconductor laser according to another modification of the first embodiment.

FIG. 14 is a plan view illustrating a semiconductor laser according to still another modification of the first embodiment.

FIG. 15 is a plan view illustrating a semiconductor laser according to a second embodiment of the present disclosure.

FIG. 16 is a cross-sectional view taken along line XVI-XVI shown in FIG. 15.

FIG. 17 is a cross-sectional view illustrating a step in an example of a method of manufacturing a semiconductor laser.

FIG. 18 is a cross-sectional view illustrating a step in an example of a method of manufacturing a semiconductor laser.

FIG. 19 is a cross-sectional view illustrating a step in an example of a method of manufacturing a semiconductor laser.

FIG. 20 is a cross-sectional view illustrating a step in an example of a method of manufacturing a semiconductor laser.

FIG. 21 is a cross-sectional view illustrating a step in an example of a method of manufacturing a semiconductor laser.

FIG. 22 is a cross-sectional view illustrating a step in an example of a method of manufacturing a semiconductor laser.

FIG. 23 is a plan view illustrating a semiconductor laser according to a modification of the second embodiment.

FIG. 24 is a plan view illustrating a semiconductor laser according to another modification of the second embodiment.

FIG. 25 is a plan view illustrating a semiconductor laser according to still another modification of the second embodiment.

FIG. 26 is a plan view illustrating a shape of a second conductor as a third modification.

FIG. 27 is a cross-sectional view illustrating a configuration of a flip-chip mounting type surface-emitting semiconductor laser according to a comparative example.

### DETAILED DESCRIPTION

A surface-emitting semiconductor laser having a semiconductor mesa portion including a vertical resonator on a substrate is known. In such a surface-emitting semiconductor laser, a pad electrode for supplying current to an electrode in contact with the semiconductor mesa portion is disposed around the semiconductor mesa portion. When the surface-emitting semiconductor laser is flip-chip mounted on a mounting surface of a wiring board, the level of the pad electrode surface needs to be sufficiently high to prevent the top surface over the semiconductor mesa portion from contacting the wiring board. In one example, the level of the pad electrode surface is equal to or higher than the level of the semiconductor mesa portion. In this case, a sub-mesa is provided above the substrate, and the pad electrode is provided above the sub-mesa. A bump such as a solder is provided on the pad electrode.

In the surface-emitting semiconductor laser having the above configuration, it is required to reduce a parasitic capacitance due to the pad electrode and improve high frequency characteristics. An object of the present disclosure is to provide a surface-emitting semiconductor laser that can reduce the parasitic capacitance due to the pad electrode.

According to the present disclosure, it is possible to provide a surface-emitting semiconductor laser that can reduce the parasitic capacitance of the pad electrode.

### DESCRIPTION OF EMBODIMENTS OF THE PRESENT DISCLOSURE

First, the contents of embodiments according to the present disclosure will be listed and described.

A first surface-emitting semiconductor laser according to a first embodiment of the present disclosure includes a substrate, a first conductive type semiconductor layer, a major mesa, a first sub-mesa, a second sub-mesa, an insulating film, a first electrode, a second electrode, a first conductor, a second conductor, a first bump, and a second bump. The substrate has a principal surface including a first region, a second region, and a third region. The first conductive type semiconductor layer is provided on the principal surface, and a portion on the first region and a portion on the third region are separated from each other. The major mesa includes a first semiconductor laminate that is provided over the first region of the substrate and on the first conductive type semiconductor layer and that serves as a distributed Bragg reflector, an active layer provided on the first semiconductor laminate, a second semiconductor laminate that is provided on the active layer and that serves as a distributed Bragg reflector, and a second conductive type semiconductor layer provided on the second semiconductor laminate. The first sub-mesa is provided over the second region of the substrate and on the first conductive type semiconductor layer. The second sub-mesa portion is provided over the third region of the substrate and on the first conductive type semiconductor layer. The insulating film has a first opening provided over the first conductive type semiconductor layer connected to the main mesa and a second opening provided over a second conductive type semiconductor layer of the major mesa, and is provided on a side surface and an upper surface of each of the major mesa, the first sub-mesa, and the second sub-mesa.

The first electrode is in contact with the first conductive type semiconductor layer through the first opening of the insulating film. The second electrode is in contact with the second conductive type semiconductor layer through the second opening of the insulating film. The first conductor includes a first pad electrode provided over the first sub-mesa and on the insulating film, and is electrically connected to the first electrode. The second conductor includes a second pad electrode provided over the second sub-mesa and on the insulating film, and extends on the insulating film along each side surface of the second sub-mesa and the major mesa to reach the second electrode. The first bump is provided on the first pad electrode. The second bump is provided on the second pad electrode.

In this surface-emitting semiconductor laser, when a driving voltage is applied between the first bump and the second bump, a driving current is supplied to the active layer through the first conductor and the first electrode, and the second conductor and the second electrode. The active layer receives the drive current to generate light. The light output from the active layer performs a laser oscillation between the first semiconductor laminate and the second semiconductor laminate, and is outputted as laser light in a direction perpendicular to the principal surface of the substrate. The first bump is provided on the first pad electrode provided over the upper surface of the first sub-mesa. The second bump is provided on the second pad electrode provided over the upper surface of the second sub-mesa. This allows flip-chip mounting of the surface-emitting semiconductor laser on a mounting surface of a wiring board while preventing the top surface over the major mesa from contacting the wiring board.

In a conventional surface-emitting semiconductor laser by flip-chip mounting, since the first conductive type semiconductor layer extends over the entire surface of the principal surface, the first conductive type semiconductor layer under the major mesa and the first conductive type semiconductor layer under the second sub-mesa are connected to each other. On the other hand, the second pad electrode that is electrically connected to the second conductive type semiconductor layer of the major mesa is provided over the upper surface of the second sub-mesa. Therefore, in the conventional surface-emitting semiconductor laser, a parasitic capacitance is generated between the first conductive type semiconductor layer under the second sub-mesa and the second pad electrode and deteriorates high frequency characteristics of the surface-emitting semiconductor laser. In response to the above issue, in the surface-emitting semiconductor laser described above, the portion on the first region and the portion on the third region in the first conductive type semiconductor layer are separated from each other. Accordingly, since a portion of the first conductive type semiconductor layer facing the second pad electrode is electrically isolated from the major mesa, the parasitic capacitance due to the second pad electrode is reduced, and high frequency characteristics of the surface-emitting semiconductor laser are improved.

In the surface-emitting semiconductor laser according to the first embodiment, the first sub-mesa and the second sub-mesa may have a laminated structure that is the same as a laminated structure of the major mesa. In this case, the first sub-mesa and the second sub-mesa having the same level as the major mesa can be easily formed.

The surface-emitting semiconductor laser according to the first embodiment may further includes a recess that extends through the first conductive type semiconductor layer to reach the substrate. The portion on the first region and the portion on the third region in the first conductive type semiconductor layer may be separated from each other by the recess. In this case, the portion on the first region and the portion on the third region in the first conductive type semiconductor layer can be easily separated only by forming the recess.

In the surface-emitting semiconductor laser according to the first embodiment, the principal surface of the substrate may further include a fourth region. The surface-emitting semiconductor laser may further include a third sub-mesa that is provided over the fourth region of the substrate and on the first conductive type semiconductor layer and a third bump that is provided over the third sub-mesa and that is insulated from both the first conductor and the second conductor. In this case, the surface-emitting semiconductor laser can be fixed more firmly and stably to the mounting surface of the wiring board.

A surface-emitting semiconductor laser according to a second embodiment of the present disclosure includes a substrate, a first conductive type semiconductor layer, a major mesa, a first sub-mesa, a second sub-mesa, an insulating film, a first electrode, a second electrode, a first conductor, a second conductor, a first bump, and a second bump. The substrate has a principal surface including a first region, a second region, and a third region. The first conductive type semiconductor layer is provided on a region including at least the first region among other regions excluding the third region on the principal surface. The major mesa includes a first semiconductor laminate that is provided over the first region of the substrate and on the first conductive type semiconductor layer and that serves as a distributed Bragg reflector, an active layer provided on the first semiconductor laminate, a second semiconductor laminate that is provided on the active layer and that serves as a distributed Bragg reflector, and a second conductive type semiconductor layer provided on the second semiconductor laminate. The first sub-mesa includes a dielectric and is provided over the second region of the substrate. The second sub-mesa includes a dielectric and is provided over the third region of the substrate. The insulating film has a first opening provided over the first conductive type semiconductor layer and a second opening provided over the second conductive type semiconductor layer, and is provided on at least an upper surface and a side surface of the major mesa. The first electrode is in contact with the first conductive type semiconductor layer through the first opening of the insulating film. The second electrode is in contact with the second conductivity-type semiconductor layer through the second opening of the insulating film. The first conductor includes a first pad electrode provided over the first sub-mesa and is electrically connected to the first electrode. The second conductor includes a second pad electrode provided over the second sub-mesa. The second conductor extends along a side surface of the second sub-mesa and extends on the insulating film along a side surface of the major mesa to reach the second electrode. The first bump is provided on the first pad electrode. The second bump is provided on the second pad electrode.

The principle of outputting laser light by this surface-emitting semiconductor laser is the same as that of the surface-emitting semiconductor laser according to the first embodiment described above. Also in this surface-emitting semiconductor laser, the first bump is provided on the first pad electrode that is provided over the upper surface of the first sub-mesa, and the second bump is provided on the second pad electrode that is provided over the second sub-mesa. Therefore, the surface-emitting semiconductor laser can be flip-chip mounted on the mounting surface of the wiring board while preventing the top surface over the major mesa from contacting the wiring board.

Further, in the surface-emitting semiconductor laser, the first conductive type semiconductor layer is provided on the region including at least the first region (i.e., the region in which the major mesa is provided) among other regions excluding the third region (i.e., the region in which the second sub-mesa is provided) in the principal surface. This means that there is no portion of the first conductive type semiconductor layer facing the second pad electrode, which reduces the parasitic capacitance due to the second pad electrode and improves high frequency characteristics of the surface-emitting semiconductor laser.

In the surface-emitting semiconductor laser according to the second embodiment, the dielectrics of the first sub-mesa and the second sub-mesa may include polyimide. In this case, the first sub-mesa and the second sub-mesa, which are equal to or higher than the major mesa in terms of the level, can be easily formed.

In the surface-emitting semiconductor laser according to the second embodiment, the principal surface of the substrate may further include a fourth region. The surface-emitting semiconductor laser may further include a third sub-mesa that includes a dielectric and is provided over the fourth region of the substrate, and a third bump that is provided over the third sub-mesa and is insulated from both of the first conductor and the second conductor. In this case, the surface-emitting semiconductor laser can be fixed more firmly and stably to the mounting surface of the wiring board.

### DETAILS OF EMBODIMENTS OF THE PRESENT DISCLOSURE

Specific examples of a surface-emitting semiconductor laser according to the present disclosure will be described below with reference to the drawings. It should be noted that the present invention is not limited to these examples, but is defined by the scope of the claims, and is intended to include all modifications within the meaning and scope equivalent to the scope of the claims. In the following description, the same elements are denoted by the same reference numerals in the description of the drawings, and redundant description will be omitted.

### First Embodiment

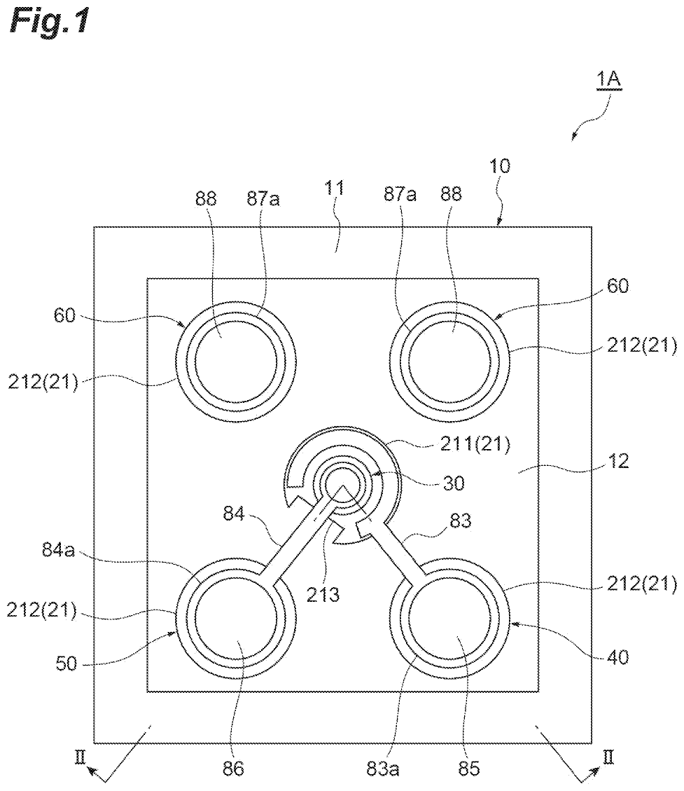

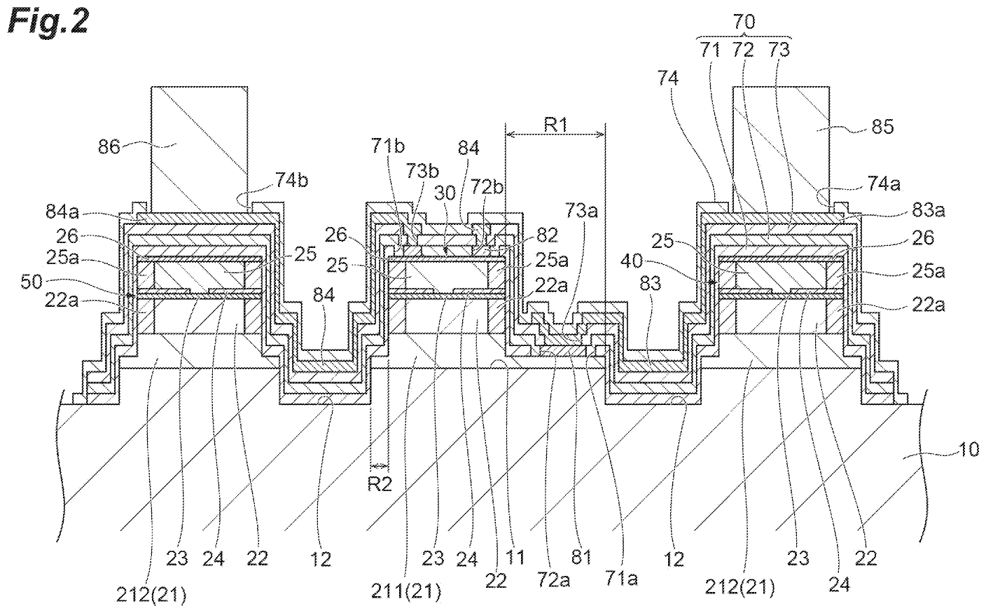

FIG. 1 is a plan view illustrating a surface-emitting semiconductor laser (hereinafter simply referred to as a semiconductor laser) according to a first embodiment of the present disclosure. FIG. 2 is a cross-sectional view taken along line II-II shown in FIG. 1. As illustrated in FIGS. 1 and 2, the semiconductor laser 1A of this embodiment includes a substrate 10, an n-type (first conductivity type) contact layer 21, a major mesa 30, a first sub-mesa 40, a second sub-mesa 50, a plurality (two in the illustrated example) of third sub-mesas 60, insulating films 70 and 74, a first electrode 81, a second electrode 82, a first conductor 83, a second conductor 84, a first bump 85, a second bump 86, and a plurality (two in the illustrated example) of third bumps 88. The insulating films 70 and 74 are omitted in FIG. 1.

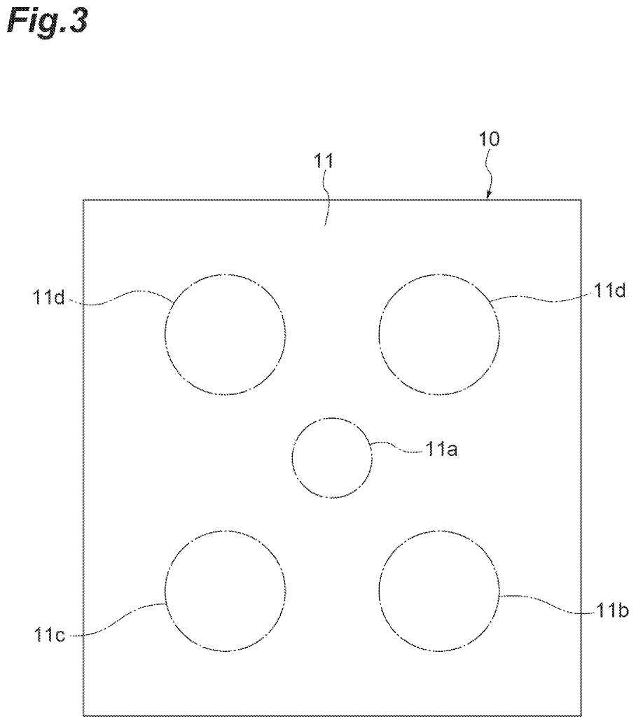

Substrate 10 is a plate-like, semi-insulating member having a principal surface 11. Substrate 10 is, for example, a group III-V compound semiconductor substrate, and one example is a GaAs substrate. FIG. 3 is a plan view illustrating principal surface 11. As illustrated in FIG. 3, principal surface 11 includes a first region 11a, a second region 11b, a third region 11c, and a plurality (two in the illustrated example) of fourth regions 11d. These regions 11a to 11d are circular, for example. First region 11a is located at the center of principal surface 11. Second region 11b, third region 11c, and the plurality of fourth regions 11d are located around first region 11a so as to surround first region 11a. In one example, a shape of principal surface 11 is a square or a rectangle, and positions of second region 11b, third region 11c, and the plurality of fourth regions 11d are respectively close to the four corners of the square or the rectangle. Specifically, each of second region 11b, third region 11c, and two fourth regions 11d is disposed near a different corner of the four corners of principal surface 11 so as to face each other.

Referring again to FIGS. 1 and 2, n-type contact layer 21 is an example of the first conductive type semiconductor layer in the present disclosure and is provided on principal surface 11. N-type contact layer 21 is an AlₓGa₁₋ₓAs layer (0<x<1), for example. A composition x of Al is 0.1, for example. N-type contact layer 21 includes a first portion 211 and a second portion 212. First portion 211 and second portion 212 are separated from each other by a recess 12. Recess 12 extends through n-type contact layer 21 and reaches substrate 10. Recess 12 extends along an outer edge of first region 11a so as to surround first region 11a. Therefore, first portion 211 is disposed on areas limited to first region 11a and its surroundings. As illustrated in FIG. 1, a planar shape of first portion 211 is nearly circular, similar to the shape of first region 11a. However, first portion 211 has a portion 213 that is recessed toward its center in a part on the circumference of first portion 211. In other words, recess 12 is formed in a part of the outer periphery of first portion 211 so as to protrude toward the center of first portion 211. In one example, a distance R1 between a side surface of major mesa 30 and a side surface of first portion 211 excluding portion 213 is in the range of 15 μm to 20 μm. The shortest distance R2 between the side surface of major mesa 30 and a side surface of portion 213 is 5 μm. Second portion 212 is divided by recess 12 into a portion including second region 11b and its surroundings, a portion including third region 11c and its surroundings, and a portion including each of fourth regions 11d and its surroundings.

Major mesa 30 is a mesa-like portion provided over first region 11a of substrate 10. Major mesa 30 has a structure for a vertical laser oscillation. Specifically, major mesa 30 includes a first semiconductor laminate 22, an active layer 23, a current confinement structure 24, a second semiconductor laminate 25, and a p-type (second conductivity type) contact layer 26. First semiconductor laminate 22 is a lower distributed Bragg reflector (DBR), and includes at least two types of layers which are alternately laminated and have different refractive indices from each other. In one example, first semiconductor laminate 22 has an AlGaAs/GaAs superlattice structure. First semiconductor laminate 22 is provided over first region 11a of substrate 10 and on first portion 211 of n-type contact layer 21. The conductivity type of first semiconductor laminate 22 is an n-type, for example. Active layer 23 is a layer that is configured to output light by injecting a current, and is provided on first semiconductor laminate 22. Active layer 23 has an AlGaAs/GaAs multi quantum well (MQW) structure, for example.

Second semiconductor laminate 25 is an upper DBR and includes at least two types of layers which are alternately laminated and have different refractive indices from each other. In one example, second semiconductor laminate 25 has an AlGaAs/GaAs superlattice structure. Second semiconductor laminate 25 is provided on active layer 23. In other words, active layer 23 is provided between first semiconductor laminate 22 and second semiconductor laminate 25. The conductivity type of second semiconductor laminate 25 is a p-type, for example. P-type contact layer 26 is an example of the second conductive type semiconductor layer in the present disclosure, and is provided on second semiconductor laminate 25. P-type contact layer 26 is a p-type GaAs layer, for example.

Current confinement structure 24 is provided between active layer 23 and second semiconductor laminate 25 (or may be provided between active layer 23 and first semiconductor laminate 22). Current confinement structure 24 is a high-resistance layer formed by thermal oxidation from the periphery of major mesa 30, and has a current path in its center for passing a current. In one example, current confinement structure 24 includes an aluminum oxide layer formed by oxidizing Al contained in AlGaAs. First semiconductor laminate 22 and second semiconductor laminate 25 also have high-resistance portions 22a and 25a near the side surface of major mesa 30, respectively due to the thermal oxidation for forming current confinement structure 24.

First sub-mesa 40, second sub-mesa 50, and each of third sub-mesas 60 are mesa-like portions provided over principal surface 11 of substrate 10 and on second portion 212 of n-type contact layer 21. First sub-mesa 40 is provided over second region 11b of principal surface 11. Second sub-mesa 50 is provided over third region 11c of principal surface 11. Each of third sub-mesas 60 is provided over fourth region 11d of principal surface 11.

First sub-mesa 40, second sub-mesa 50, and each of third sub-mesas 60 of this embodiment have the same laminated structure as major mesa 30 described above. That is, each of first sub-mesa 40, second sub-mesa 50, and third sub-mesas 60 includes first semiconductor laminate 22, active layer 23, current confinement structure 24, second semiconductor laminate 25, and p-type contact layer 26. However, second semiconductor laminate 25 and p-type contact layer 26 which are included in first sub-mesa 40, second sub-mesa 50, and each of third sub-mesas 60 are inactivated by proton implantation.

Insulating film 70 includes a first insulating film 71, a second insulating film 72, and a third insulating film 73 that are laminated in order. Each of first insulating film 71, second insulating film 72, and third insulating film 73 includes a silicon-based inorganic insulator such as SiON and SiN. First insulating film 71, second insulating film 72, and third insulating film 73 are provided on the side surfaces and the upper surfaces of major mesa 30, first sub-mesa 40, second sub-mesa 50, and each of third sub-mesas 60. In addition, insulating film 70 is also provided on principal surface 11 including the bottom surface and the side surface of recess 12. First insulating film 71, second insulating film 72, and third insulating film 73 have openings 71a, 72a, and 73a provided over first portion 211 of n-type contact layer 21 which is connected to major mesa 30, respectively. First insulating film 71, second insulating film 72, and third insulating film 73 have openings 71b, 72b, and 73b provided over p-type contact layer 26 of major mesa 30, respectively. Opening 72a is an example of a first opening in the present disclosure, and opening 72b is an example of a second opening in the present disclosure.

First electrode 81 is a metallic film provided in opening 72a of second insulating film 72, and is in an ohmic contact with n-type contact layer 21 under major mesa 30 through opening 72a. First electrode 81 is made of AuGe/Ni, for example. For reliable electrical contact, the planar shape of first electrode 81 is a circular arc-like shape extending along the side surface of major mesa 30. Second electrode 82 is a metallic film provided in opening 72b of insulating film 72, and is in an ohmic contact with p-type contact layer 26 of major mesa 30 through opening 72b. For reliable electrical contact, second electrode 82 has a closed stripe shape (for example, a ring shape) on p-type contact layer 26. Laser light is emitted from the inside of the ring.

First conductor 83 is electrically connected to first electrode 81, and is a metallic film in one example. First conductor 83 includes a first pad electrode 83a provided over first sub-mesa 40 and on insulating film 70. First conductor 83 extends on insulating film 70 along each side surface of first sub-mesa 40 and major mesa 30, and reaches first electrode 81. The planar shape of a portion of first conductor 83 on first electrode 81 is a circular arc-like shape which overlaps with first electrode 81.

Second conductor 84 is electrically connected to second electrode 82, and is a metallic film in one example. Second conductor 84 includes a second pad electrode 84a provided over second sub-mesa 50 and on insulating film 70. Second conductor 84 extends on insulating film 70 along each side surface of second sub-mesa 50 and major mesa 30, and passes through the opening portion of the circular arc of first electrode 81 to reach second electrode 82. The planar shape of a portion of second conductor 84 on second electrode 82 is a ring-like shape which overlaps with second electrode 82.

As illustrated in FIG. 1, third pad electrode 87a is provided over each of third sub-mesas 60 and on insulating film 70. Each of third bumps 88 is provided on each of third pad electrodes 87a each provided over the upper surfaces of third sub-mesas 60. Third pad electrodes 87a and third bumps 88 are insulated from both of first conductor 83 and second conductor 84. In this embodiment, each of third pad electrodes 87a is provided only over each upper surface of third sub-mesas 60.

Insulating film 74 is a protective film that covers insulating film 70, first conductor 83 and second conductor 84. Insulating film 74 includes silicon nitride such as SiN, for example. Insulating film 74 has an opening 74a that is located over first pad electrode 83a to expose first pad electrode 83a, an opening 74b that is located over second pad electrode 84a to expose second pad electrode 84a, and an opening (not shown) that is located over third pad electrode 87a to expose third pad electrode 87a. First bump 85 is provided on first pad electrode 83a exposed in the opening 74a. Second bump 86 is provided on second pad electrode 84a exposed in the opening 74b. Third bump 88 is provided on third pad electrode 87a exposed in the opening (not shown) of insulating film 74. First bump 85, second bump 86, and third bump 88 mainly contain gold, for example.

In this semiconductor laser 1A, when a driving voltage is applied between first bump 85 and second bump 86, a driving current is supplied to active layer 23 through first conductor 83 and first electrode 81, and second conductor 84 and second electrode 82. Active layer 23 receives the drive current to generate light. The light outputted from active layer 23 performs laser oscillation between first semiconductor laminate 22 and second semiconductor laminate 25 to emit laser light in a direction perpendicular to principal surface 11 of substrate 10.

Effects obtained by semiconductor laser 1A of the present embodiment described above will be described below. First bump 85 is provided on first pad electrode 83a that is provided over first sub-mesa 40. Second bump 86 is provided on second pad electrode 84a that is provided over second sub-mesa 50. This enables flip-chip mounting of semiconductor laser 1A to a mounting surface of a wiring board while preventing a top surface over major mesa 30 from contacting the wiring board.

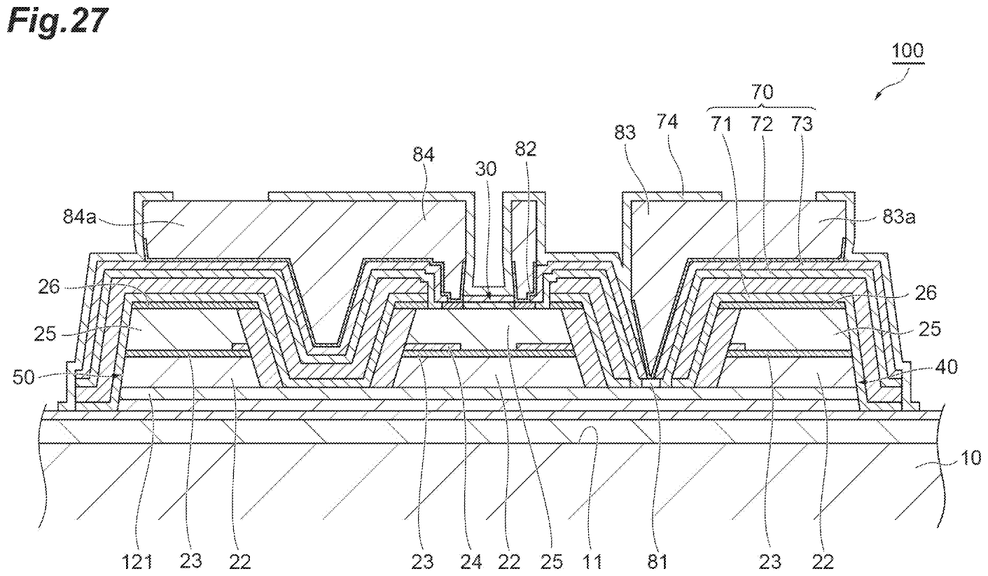

FIG. 27 is a cross-sectional view illustrating a configuration of a flip-chip mounting type surface-emitting semiconductor laser 100 according to a comparative example. As illustrated in the figure, in this surface-emitting semiconductor laser 100, an n-type contact layer 121 extends over a wide area on a principal surface 11 of a substrate 10, and n-type contact layer 121 over a major mesa 30 and n-type contact layer 121 under a second sub-mesa 50 are connected to each other. On the other hand, a second pad electrode 84a electrically connected to a p-type contact layer 26 of major mesa 30 is provided over an upper surface of second sub-mesa 50. Therefore, in the semiconductor laser 100 of the comparative example, a parasitic capacitance is generated between n-type contact layer 121 under second sub-mesa 50, and second pad electrode 84a. This parasitic capacitance deteriorates high frequency characteristics of semiconductor laser 100. In an example calculated by setting second pad electrode 84a to a certain size, a parasitic capacitance is 95 fF.

To address this issue, in the semiconductor laser 1A of the present embodiment, first portion 211 on first region 11a and second portion 212 on third region 11c in n-type contact layer 21 are separated from each other. Accordingly, since second portion 212 of n-type contact layer 21 facing second pad electrode 84a is electrically isolated from major mesa 30, the parasitic capacitance due to second pad electrode 84a is reduced, and high frequency characteristics of semiconductor laser 1A are improved. The parasitic capacitance (for example, 95 fF) due to second pad electrode 84a in the semiconductor laser 100 of the comparative example is theoretically reduced to substantially zero in the present embodiment. According to the calculation by the inventor, when the parasitic capacitance is reduced by 60 fF, a bandwidth is improved by 1.3 GHz at 25° C., and by 0.7 GHz at 85° C.

As in the present embodiment, first sub-mesa 40, second sub-mesa 50, and each of third sub-mesas 60 may have the same laminated structure as major mesa 30. In this case, since first sub-mesa 40, second sub-mesa 50, and each of third sub-mesas 60 can be formed simultaneously when major mesa 30 is formed by etching, first sub-mesa 40, second sub-mesa 50, and each of third sub-mesas 60 having the same level as major mesa 30 can be easily formed.

As in the present embodiment, semiconductor laser 1A may further include a recess 12 that extends through n-type contact layer 21 to reach substrate 10, and first portion 211 on first region 11a and second portion 212 on third region 11c in n-type contact layer 21 may be separated from each other by recess 12. In this case, first portion 211 and second portion 212 of n-type contact layer 21 can be easily separated only by forming recess 12.

As in the present embodiment, principal surface 11 of substrate 10 may include fourth region 11d, and semiconductor laser 1A may be provided with a third sub-mesa 60 provided over fourth region 11d of substrate 10 and on n-type contact layer 21, and a third bump 88 that is provided over third sub-mesa 60 and that is insulated from both of first conductor 83 and second conductor 84. In this case, since third bump 88 can be fixed to the mounting surface of the wiring board in addition to first bump 85 and second bump 86, semiconductor laser 1A can be more firmly and stably fixed to the mounting surface.

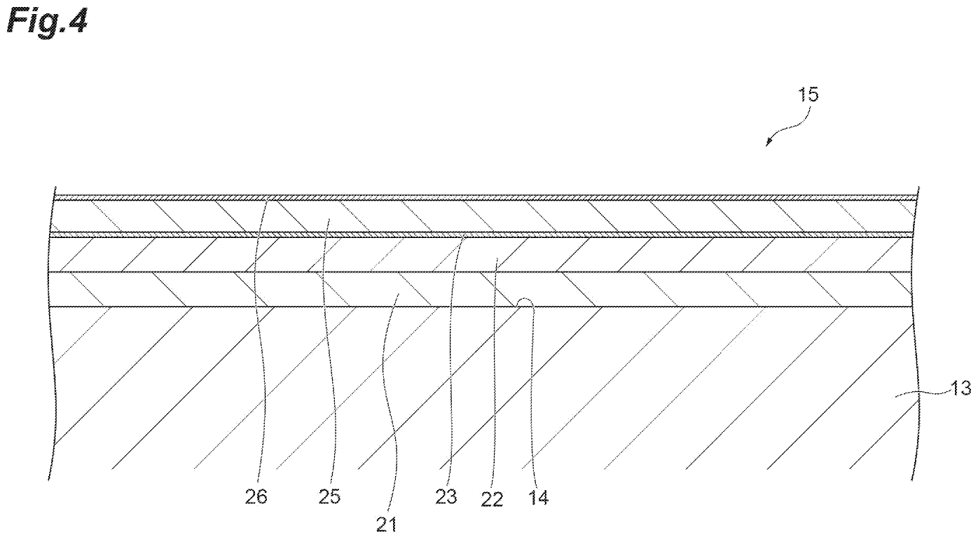

A method of manufacturing a semiconductor laser 1A according to the present embodiment will be described below. FIGS. 4 to 11 are cross-sectional views illustrating each step in an example of the manufacturing method of semiconductor laser 1A, and illustrate cross-sections taken along line II-II in FIG. 1.

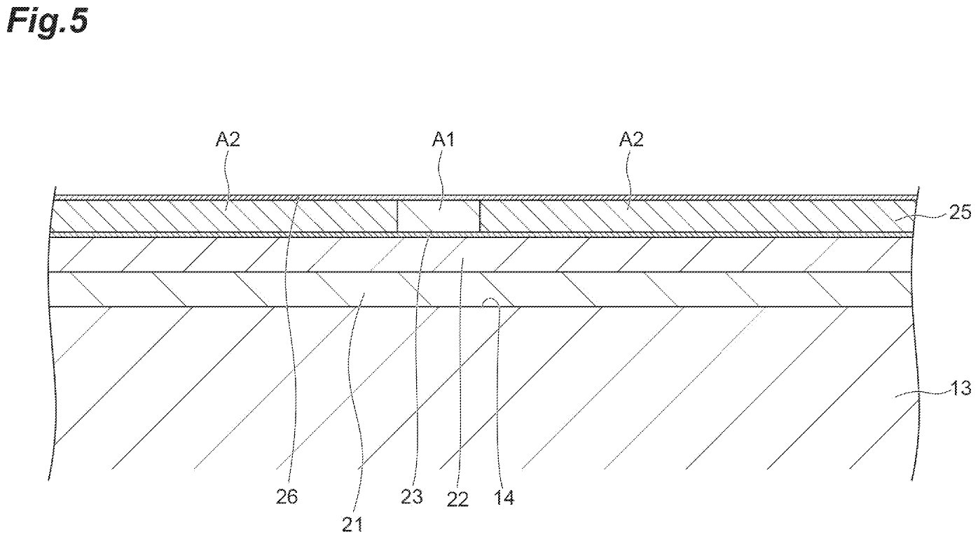

First, as illustrated in FIG. 4, n-type contact layer 21, first semiconductor laminate 22, active layer 23, second semiconductor laminate 25, and p-type contact layer 26 are epitaxially grown in this order on principal surface 14 of a wafer 13 serving as a source of substrate 10 by using, for example, a metal organic chemical vapor deposition (MOCVD) method. By this step, an epitaxial wafer 15 is obtained. Next, as illustrated in FIG. 5, protons are implanted into second semiconductor laminate 25 and p-type contact layer 26 in an area A2 other than an area A1 where major mesa 30 is to be formed to inactivate area A2.

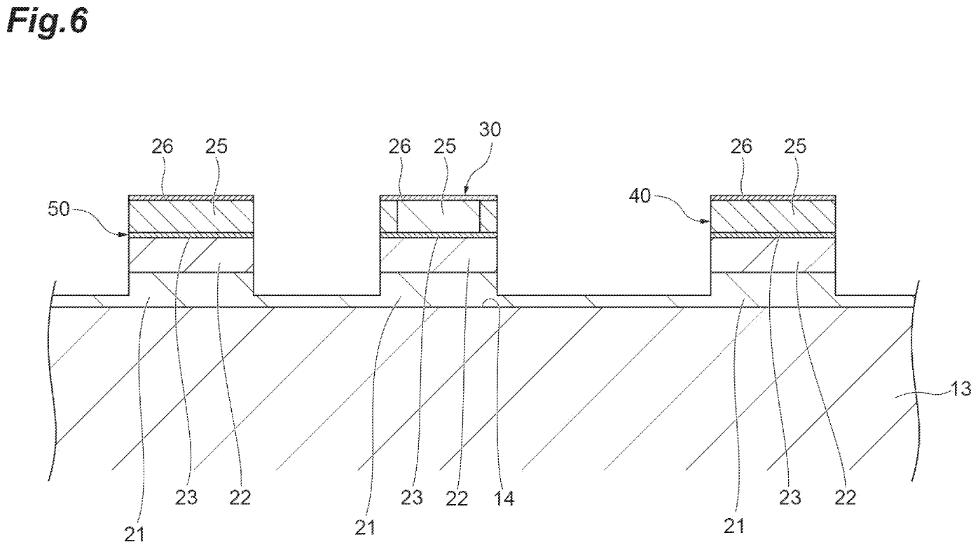

Subsequently, as illustrated in FIG. 6, layers 21 to 26 are etched to form major mesa 30, first sub-mesa 40, second sub-mesa 50, and a plurality of third sub-mesas 60. Specifically, a resist mask having openings over first region 11a, second region 11b, third region 11c, and a plurality of fourth regions 11d is formed on p-type contact layer 26, and portions of layers 21 to 26 exposed from the resist mask are etched. At this time, the etching is stopped in the middle of n-type contact layer 21. The etching is performed by dry etching, for example.

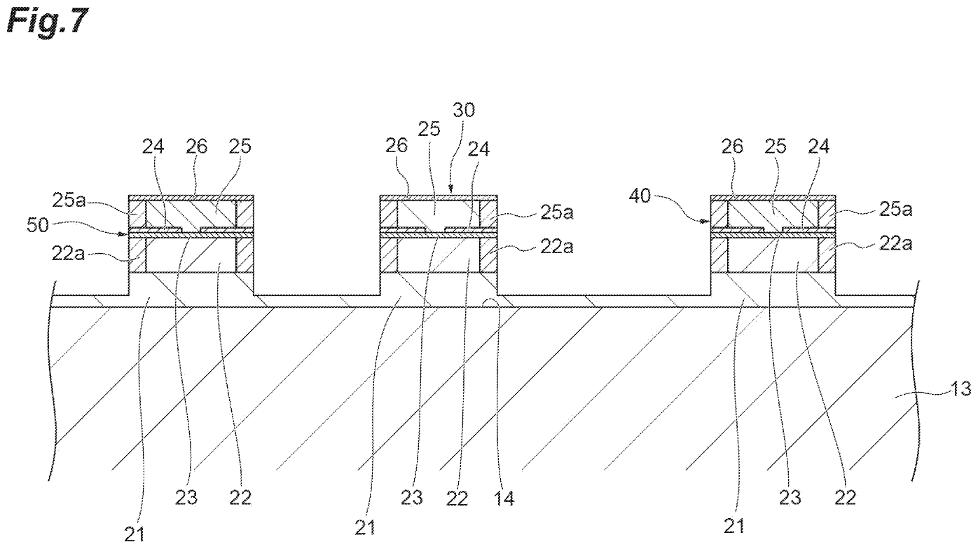

Subsequently, as illustrated in FIG. 7, epitaxial wafer 15 is placed in a high-temperature atmosphere to subject thermal oxidation to side surfaces of mesas 30, 40, 50, and 60. As a result, the side surfaces of first semiconductor laminate 22 and second semiconductor laminate 25 are oxidized to form high-resistance portions 22a and 25a, and a part of second semiconductor laminate 25 near active layer 23 is also increased in resistance to form a current confinement structure 24.

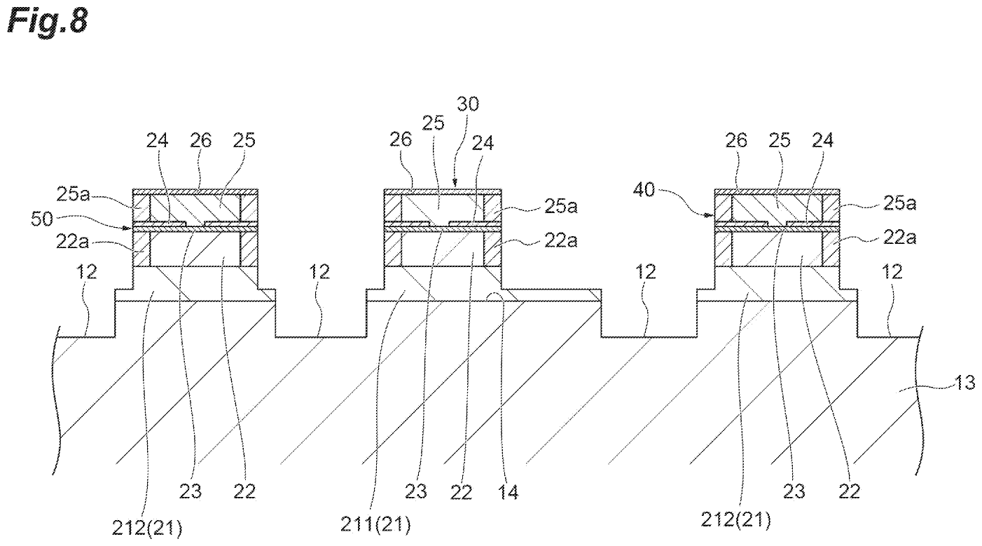

Subsequently, as illustrated in FIG. 8, recess 12 is formed so as to extend through n-type contact layer 21 to reach wafer 13. Recess 12 is formed by, for example, photolithography and dry etching. By this step, first portion 211 and second portion 212 of n-type contact layer 21 are formed, and first portion 211 and second portion 212 are separated from each other by recess 12.

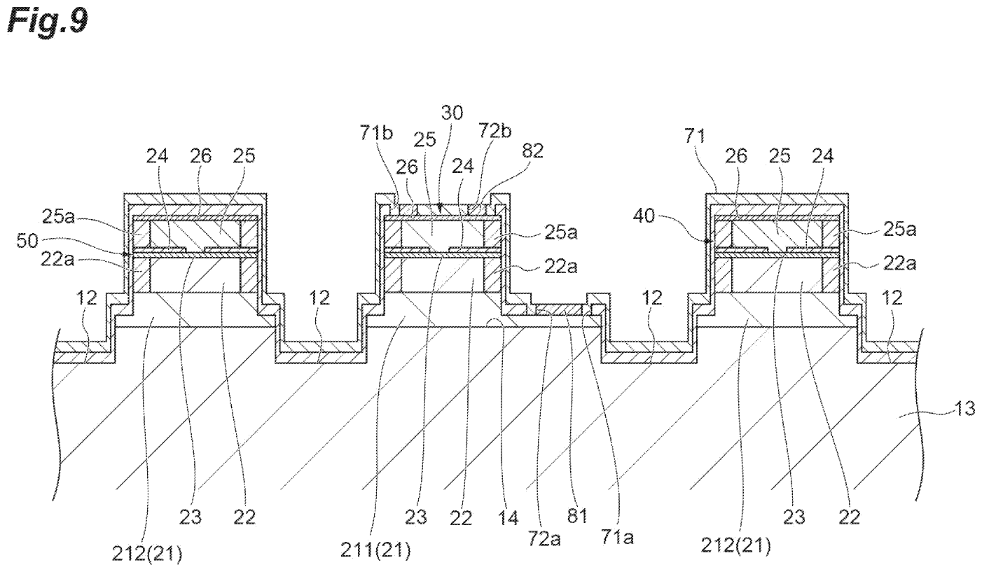

As shown in FIG. 9, first insulating film 71 of insulating film 70 is then formed. First insulating film 71 is formed by a vapor deposition method such as a plasma CVD method. Opening 71a is formed in a portion of first insulating film 71 provided on portion 211 of n-type contact layer 21. Opening 71b is formed in a portion of first insulating film 71 provided on p-type contact layer 26 of major mesa 30. Openings 71a and 71b are formed by, for example, photolithography and etching. Then, second insulating film 72 is formed to cover first insulating film 71. Second insulating film 72 is formed by, for example, a vapor deposition method such as a plasma CVD method. Opening 72a is formed in a portion of second insulating film 72 on first portion 211 of n-type contact layer 21. Opening 72b is formed in a portion of second insulating film 72 on p-type contact layer 26 of major mesa 30. Opening 72a and 72b are formed by, for example, photolithography and etching.

Subsequently, first electrode 81 is formed on n-type contact layer 21 exposed in opening 72a, and second electrode 82 is formed on p-type contact layer 26 exposed in opening 72b. First electrode 81 and second electrode 82 are formed, for example, by vapor deposition, plating, or sputtering. Patterning of first electrode 81 and second electrode 82 is performed by, for example, photolithography and etching, or lift-off.

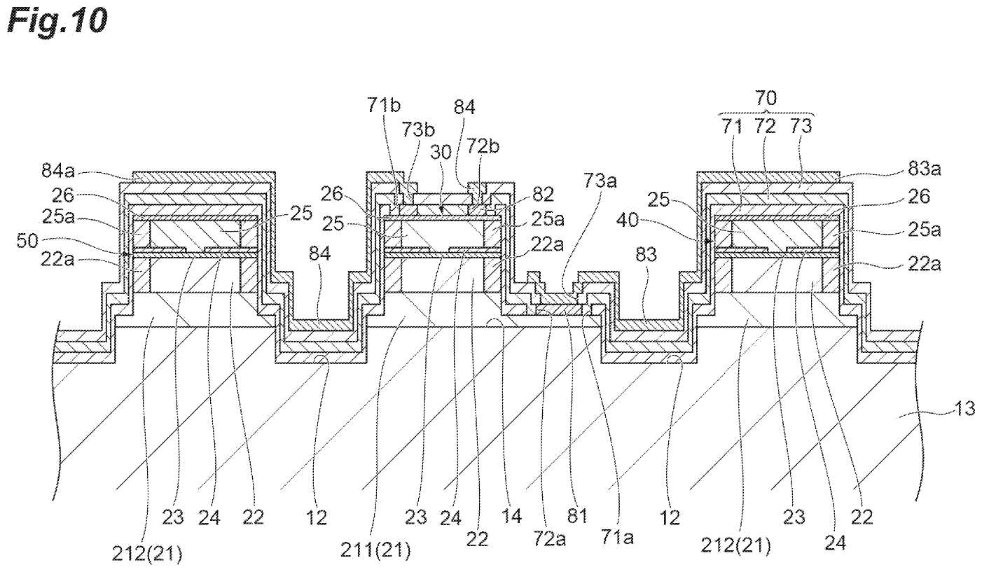

Subsequently, as illustrated in FIG. 10, third insulating film 73 is formed to cover second insulating film 72. Third insulating film 73 is formed by, for example, a vapor phase growth method such as a plasma CVD method. Opening 73a is formed in a portion of third insulating film 73 on first electrode 81. Opening 73b is formed in a portion of third insulating film 73 on second electrode 82. Openings 73a and 73b are formed by, for example, photolithography and etching. Then, first conductor 83 is formed so as to reach the top surface over first sub-mesa 40 from first electrode 81. Second conductor 84 is formed so as to reach the top surface over second sub-mesa 50 from second electrode 82. First conductor 83 and second conductor 84 are formed by, for example, a lift-off method, a vapor deposition method, and a plating method. At this time, first pad electrode 83a, second pad electrode 84a, and third pad electrode 87a are formed simultaneously with first conductor 83 and second conductor 84.

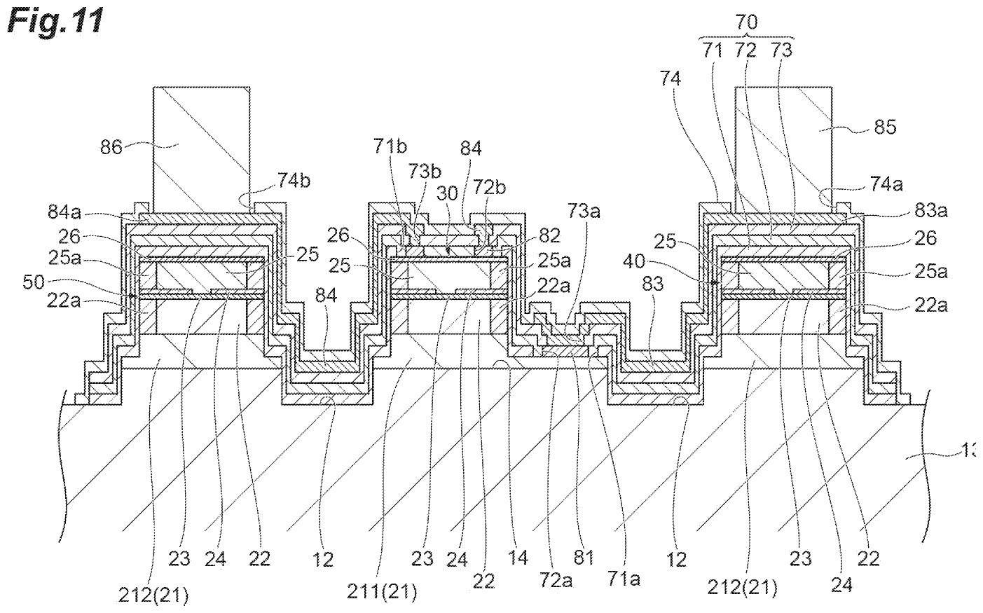

Subsequently, as illustrated in FIG. 11, insulating film 74 is formed. Insulating film 74 is formed by a vapor deposition method such as a plasma CVD method. Opening 74a is formed in a portion of insulating film 74 on first pad electrode 83a. Opening 74b is formed in a portion of insulating film 74 on second pad electrode 84a. An opening (not shown) is formed in a portion of insulating film 74 on third pad electrode 87a. Openings 74a and the 74b are formed by, for example, photolithography and etching. Then, first bump 85 is formed on first pad electrode 83a exposed in opening 74a. Second bump 86 is formed on second pad electrode 84a exposed in opening 74b. Third bump 88 is formed on third pad electrode 87a exposed in the opening (not shown) of insulating film 74. First bump 85, second bump 86, and third bump 88 are formed by, for example, vapor deposition and lift-off. Finally, wafer 13 is cut into chips to form substrate 10. Through the above-described steps, semiconductor laser 1A of the present embodiment is manufactured.

First Modification

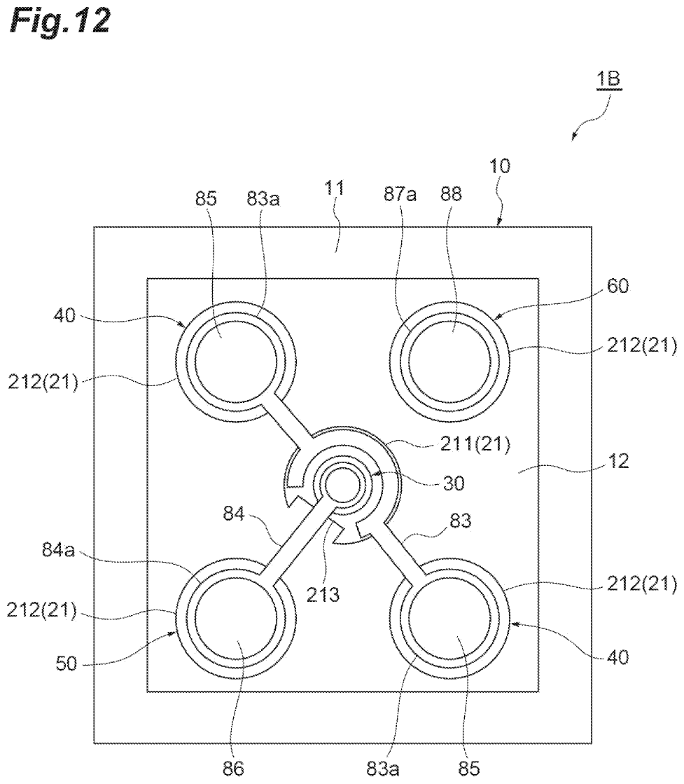

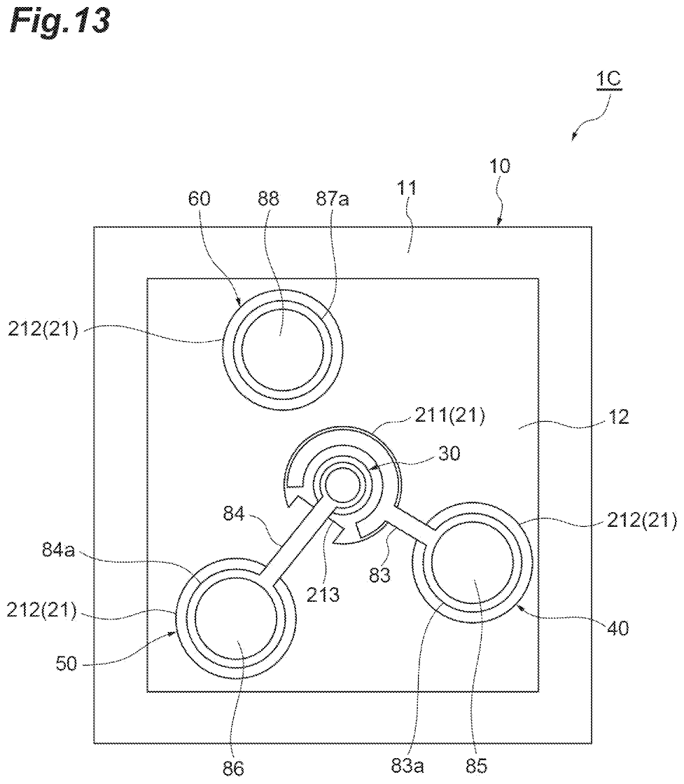

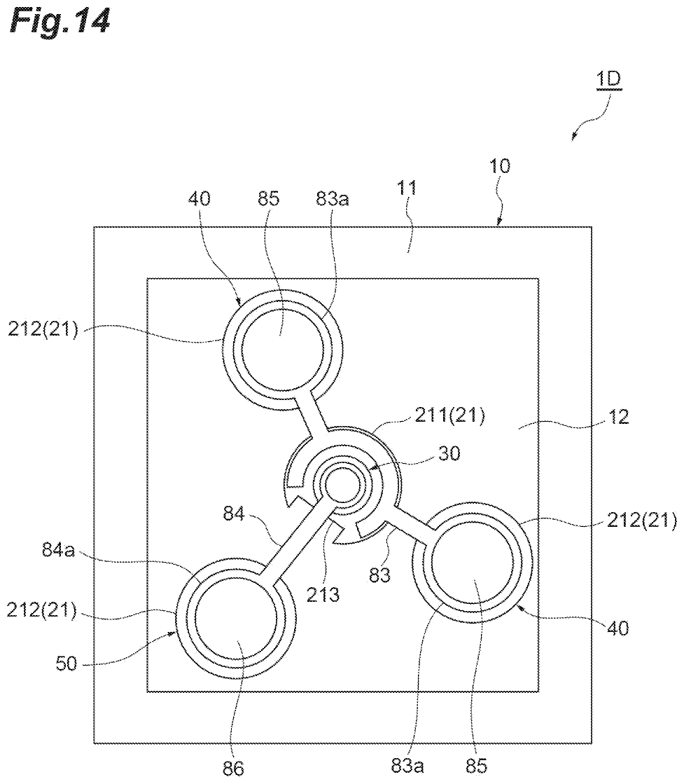

FIG. 12 is a plan view illustrating a semiconductor laser 1B according to a modification of the first embodiment. Semiconductor laser 1B is different from the first embodiment in that a plurality (two in the illustrated example) of first sub-mesas 40 are provided and that only one third sub-mesa 60 is provided. First pad electrode 83a is provided over an upper surface of each of first sub-mesas 40, and first bump 85 is provided on each of first pad electrodes 83a. FIG. 13 is a plan view illustrating a semiconductor laser 1C according to another modification of the first embodiment. This semiconductor laser 1C is different from the first embodiment in that only one third sub-mesa 60 is provided. FIG. 14 is a plan view illustrating a semiconductor laser 1D according to still another modification of the first embodiment. This semiconductor laser 1D is different from the first embodiment in that a plurality (two in the illustrated example) of first sub-mesas 40 are provided and that third sub-mesa 60 is not provided. The semiconductor lasers 1B, 1C, and 1D according to the modifications illustrated in FIGS. 12, 13, and 14 can also have the same effects as those of the first embodiment.

### Second Embodiment

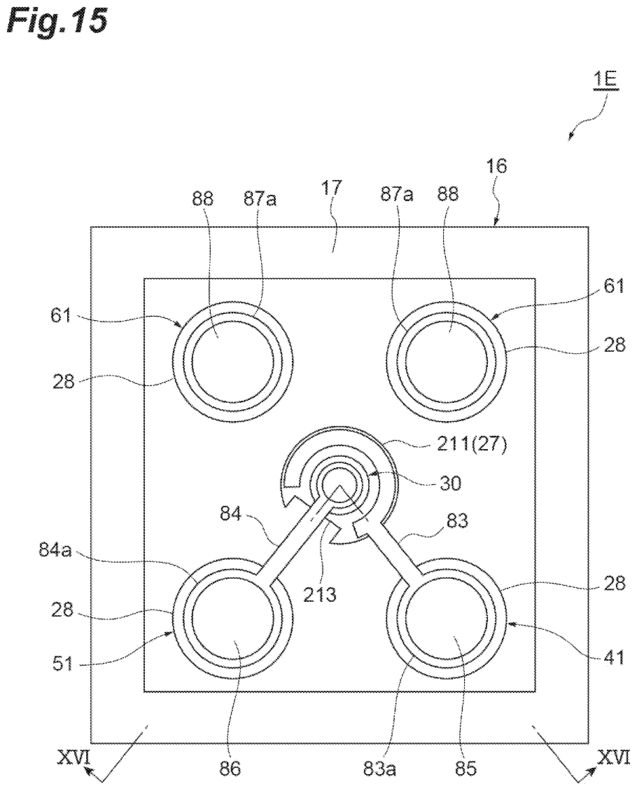

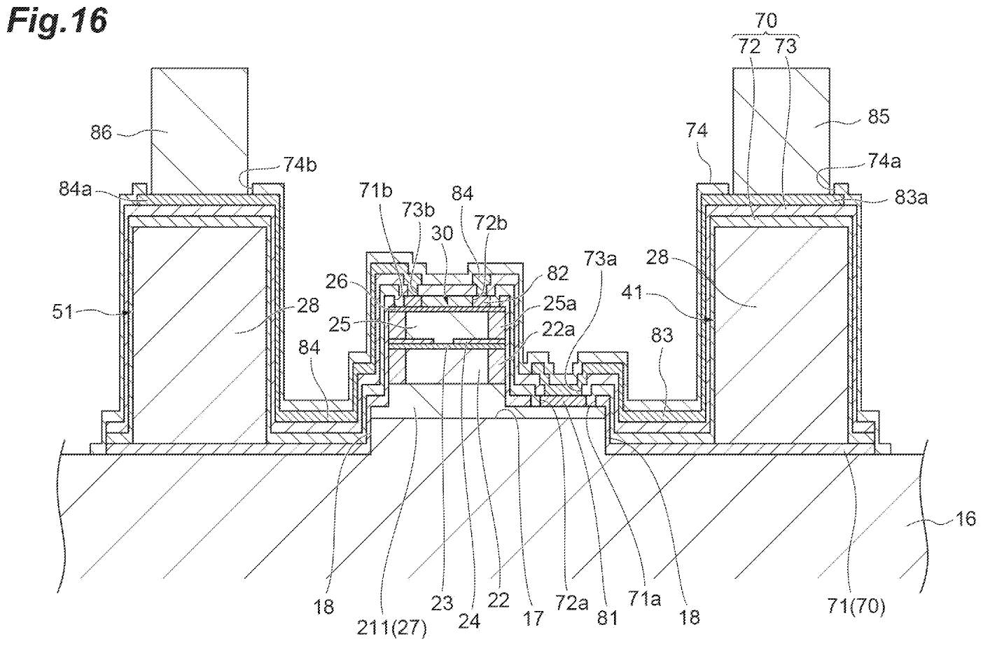

FIG. 15 is a plan view illustrating a semiconductor laser 1E according to a second embodiment of the present disclosure. FIG. 16 is a cross-sectional view taken along line XVI-XVI in FIG. 15. As illustrated in FIGS. 15 and 16, semiconductor laser 1E of this embodiment includes substrate 16, n-type contact layer 27, major mesa 30, first sub-mesa 41, second sub-mesa 51, a plurality (two in the illustrated example) of third sub-mesas 61, insulating films 70 and 74, first electrode 81, second electrode 82, first conductor 83, second conductor 84, first bump 85, second bump 86, and a plurality (two in the illustrated example) of third bumps 88. Among them, the configurations of major mesa 30, insulating films 70 and 74, first electrode 81, second electrode 82, first conductor 83, second conductor 84, first bump 85, second bump 86, and the plurality of third bumps 88 are the same as those in the first embodiment. Insulating films 70 and 74 are omitted in FIG. 15.

Substrate 16 is a plate-like, semi-insulating member having principal surface 17. The material of substrate 16 is the same as that of substrate 10 in the first embodiment. Principal surface 17 includes first region 11a, second region 11b, third region 11c, and a plurality of fourth regions 11d, in the same manner as principal surface 11 of the first embodiment (see FIG. 3).

N-type contact layer 27 is an example of a first conductive type semiconductor layer in the present disclosure and is provided on principal surface 17. The material and composition of n-type contact layer 27 are the same as those of n-type contact layer 21 of the first embodiment. N-type contact layer 27 of the present embodiment is provided on a region including at least first region 11a among other regions excluding third region 11c on principal surface 17. In one example, n-type contact layer 27 is provided only on first region 11a and its surroundings, and includes only first portion 211. Portions of n-type contact layer 27 other than first portion 211 are removed by etching. By this etching, a step 18 is formed on principal surface 17. Therefore, due to step 18, the level of region other than first region 11a in principal surface 17 is lower than the level of first region 11a.

First sub-mesa 41, second sub-mesa 51, and each of third sub-mesas 61 are mesa-like portions provided over principal surface 17 of substrate 16 (on first insulating film 71 in the illustrated example). First sub-mesa 41 is provided over second region 11b of principal surface 17. Second sub-mesa 51 is provided over third region 11c of principal surface 17. Each of third sub-mesas 61 is provided over fourth region 11d of principal surface 17. The structures of first sub-mesa 41, second sub-mesa 51, and each of third sub-mesas 61 in this embodiment are different from the structure of major mesa 30. First sub-mesa 41, second sub-mesa 51, and each of third sub-mesa 61 include a dielectric block 28, respectively. In one example, first sub-mesa 41, second sub-mesa 51, and each of third sub-mesa 61 consist of only dielectric block 28. A dielectric of dielectric block 28 includes, for example, a resin, and in one example, includes photosensitive polyimide. The level of an upper surface (in other words, the position of an upper surface in the normal direction of principal surface 17) of each of first sub-mesa 41, second sub-mesa 51, and third sub-mesas 61 is substantially equal to or higher than an upper surface of major mesa 30. Alternatively, the level of the upper surface of each of first sub-mesa 41, second sub-mesa 51, and third sub-mesa 61 may be lower than the upper surface of major mesa 30 as long as the levels of a top of first bump 85, second bump 86, and third bump 88 are higher than the upper surface of major mesa 30.

First insulating film 71 of insulating film 70 is provided on a side surface and an upper surface of major mesa 30 and on principal surface 17. Second insulating film 72 and third insulating film 73 are provided on side surfaces and upper surfaces of major mesa 30, first sub-mesa 41, second sub-mesa 51, and each of third sub-mesas 61. First pad electrode 83a of first conductor 83 is provided over first sub-mesa 41 and on third insulating film 73. First conductor 83 extends on third insulating film 73 along each side surface of first sub-mesa 41 and major mesa 30 to reach first electrode 81. Second pad electrode 84a of second conductor 84 is provided over second sub-mesa 51 and on third insulating film 73. Second conductor 84 extends on third insulating film 73 along each side surface of second sub-mesa 51 and major mesa 30 to reach second electrode 82. Third pad electrode 87a is provided over each of third sub-mesas 61 and on third insulating film 73.

Effects obtained by semiconductor laser 1E of the present embodiment described above will be described below. First bump 85 is provided on first pad electrode 83a that is provided over the upper surface of first sub-mesa 41. Second bump 86 is provided on second pad electrode 84a that is provided over the upper surface of second sub-mesa 51. This enables flip-chip mounting of semiconductor laser 1E to a mounting surface of a wiring board while preventing the top surface over major mesa 30 from contacting the wiring board.

In the semiconductor laser 1E of the present embodiment, n-type contact layer 27 is provided on a region including at least first region 11a (i.e., a region where major mesa 30 is to be provided) among regions other than third region 11c (i.e., a region where second sub-mesa 51 is to be provided) on principal surface 17. This reduces a parasitic capacitance due to second pad electrode 84a and improves high frequency characteristics of semiconductor laser 1E because there is no portion of n-type contact layer 27 that faces second pad electrode 84a.

As in the present embodiment, dielectrics of first sub-mesa 41 and second sub-mesa 51 may include polyimide. In this case, first sub-mesa 41 and second sub-mesa 51 which are equal to or higher than major mesa 30 can be easily formed.

As in the present embodiment, principal surface 17 of substrate 16 may further include fourth region 11d, and surface-emitting semiconductor laser 1E may further include third sub-mesa 61 that includes a dielectric and that is provided over fourth region 11d of substrate 16, and third bump 88 that is provided over third sub-mesa 61 and that is insulated from both of first conductor 83 and second conductor 84. In this case, in addition to first bump 85 and second bump 86, third bump 88 can be fixed to the mounting surface of the wiring board, so that semiconductor laser 1E can be more firmly and stably fixed to the mounting surface.

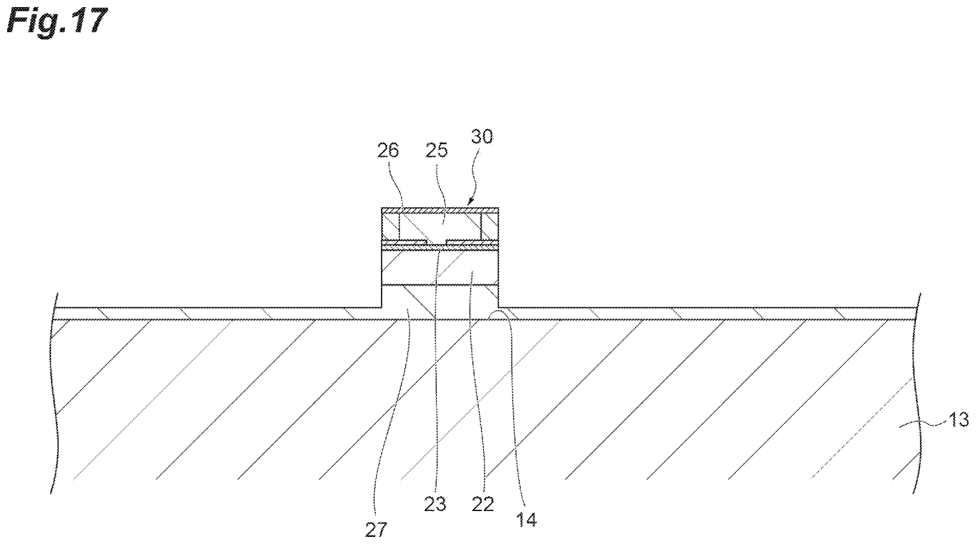

A method of manufacturing semiconductor laser 1E according to the present embodiment will now be described below. FIGS. 17 to 22 are cross-sectional views illustrating each step in an example of the manufacturing method of semiconductor laser 1E, and illustrate cross-sections taken along line XVI-XVI shown in FIG. 15.

First, in the same way as the step illustrated in FIG. 4 of the first embodiment, n-type contact layer 27, first semiconductor laminate 22, active layer 23, second semiconductor laminate 25, and p-type contact layer 26 are epitaxially grown in this order on principal surface 14 of wafer 13 from which substrate 16 is formed. Thus, an epitaxial wafer is obtained. Next, in the same way as the step shown in FIG. 5, protons are implanted into second semiconductor laminate 25 and p-type contact layer 26 in area A2 other than area A1 where major mesa 30 is to be formed to inactivate area A2.

Subsequently, as illustrated in FIG. 17, layers 22 to 27 are etched to form major mesa 30. Specifically, a resist mask having an opening over first region 11a is formed on p-type contact layer 26, and portions of layers 22 to 27 exposed from the resist mask are etched. At this time, the etching is stopped in the middle of n-type contact layer 27. The etching is performed by dry etching, for example.

Subsequently, the epitaxial wafer is placed in a high-temperature atmosphere to subject thermal oxidation to a side surface of major mesa 30. As a result, the side surfaces of first semiconductor laminate 22 and second semiconductor laminate 25 are oxidized to form high-resistance portions 22a and 25a, and a part of second semiconductor laminate 25 near active layer 23 is increased in resistance to form current confinement structure 24.

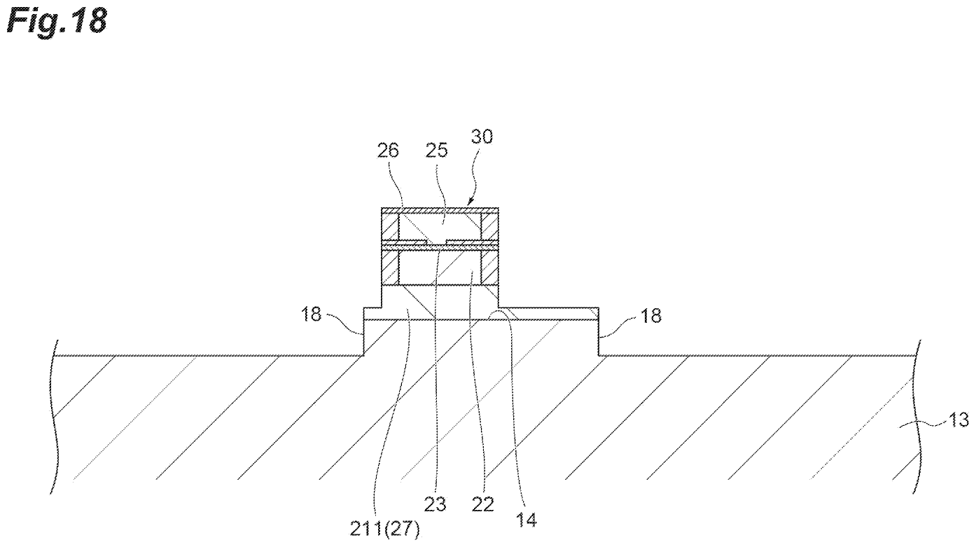

Subsequently, as illustrated in FIG. 18, n-type contact layer 27 on regions other than first region 11a and its surroundings is removed by etching. This etching is continued even after wafer 13 is exposed. Thus, step 18 is formed on principal surface 14. Step 18 is formed by dry etching, for example. After the etching, n-type contact layer 27 has only first portion 211.

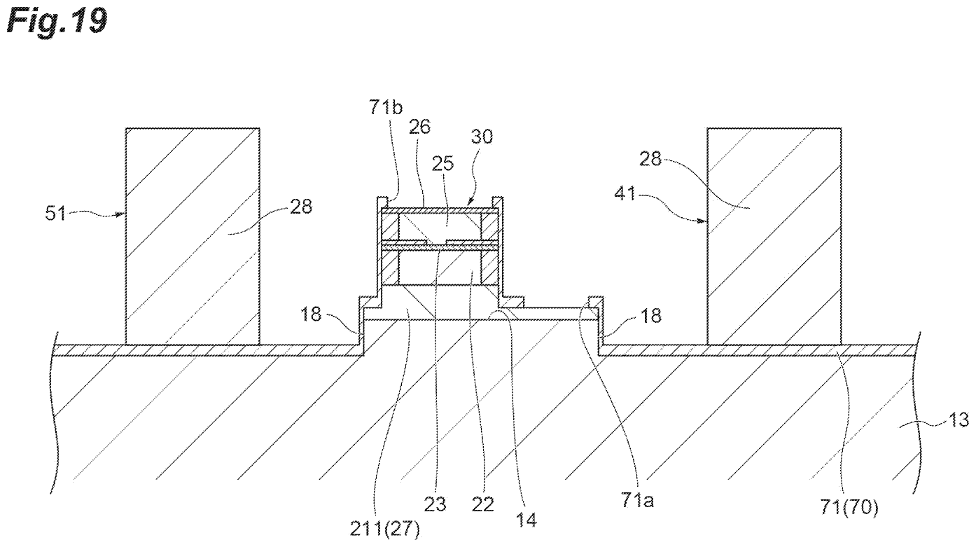

Subsequently, as illustrated in FIG. 19, first insulating film 71 of insulating film 70 is formed. Opening 71a is formed in a portion of first insulating film 71 provided on n-type contact layer 27. Opening 71b is formed in a portion of first insulating film 71 provided on p-type contact layer 26. Openings 71a and 71b are formed by etching, for example. Then, a dielectric block 28 for first sub-mesa 41 is formed over second region 11b and on first insulating film 71. Dielectric block 28 for second sub-mesa 51 is formed over third region 11c and on first insulating film 71. Dielectric block 28 for third sub-mesa 61 is formed over fourth region 11d and on first insulating film 71. When these dielectric blocks are made of photosensitive polyimide, liquid photosensitive polyimide is applied to the entire surface of principal surface 14, and then exposed and developed. After that, unnecessary portions of photosensitive polyimide are removed, followed by curing.

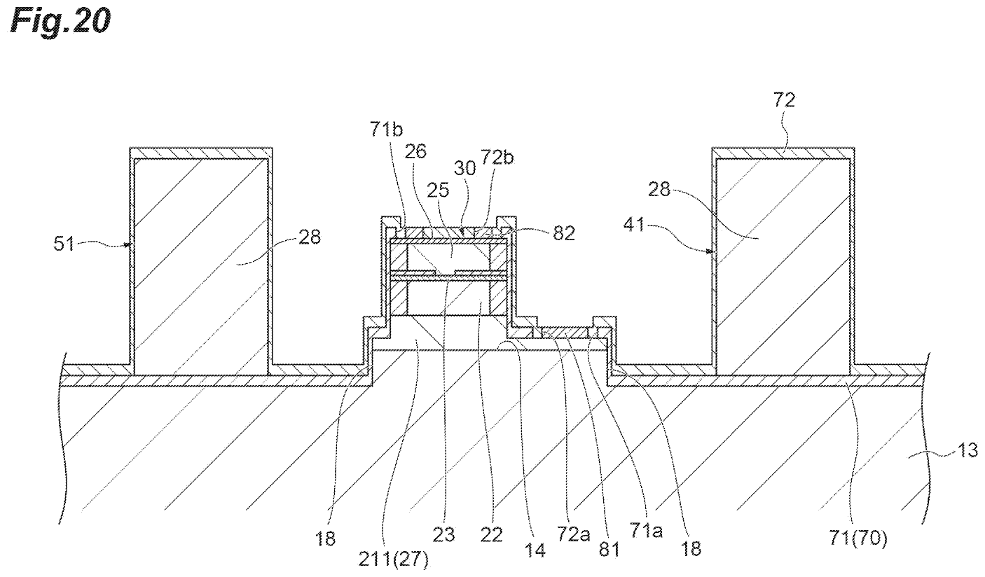

Subsequently, as illustrated in FIG. 20, second insulating film 72 is formed so as to cover first insulating film 71 and each of dielectric blocks 28. Opening 72a is formed in a portion of second insulating film 72 that is provided on n-type contact layer 27. Opening 72b is formed in a portion of second insulating film 72 that is provided on p-type contact layer 26 of major mesa 30. Then, first electrode 81 is formed on n-type contact layer 27 exposed in opening 72a. Second electrode 82 is formed on p-type contact layer 26 exposed in opening 72b.

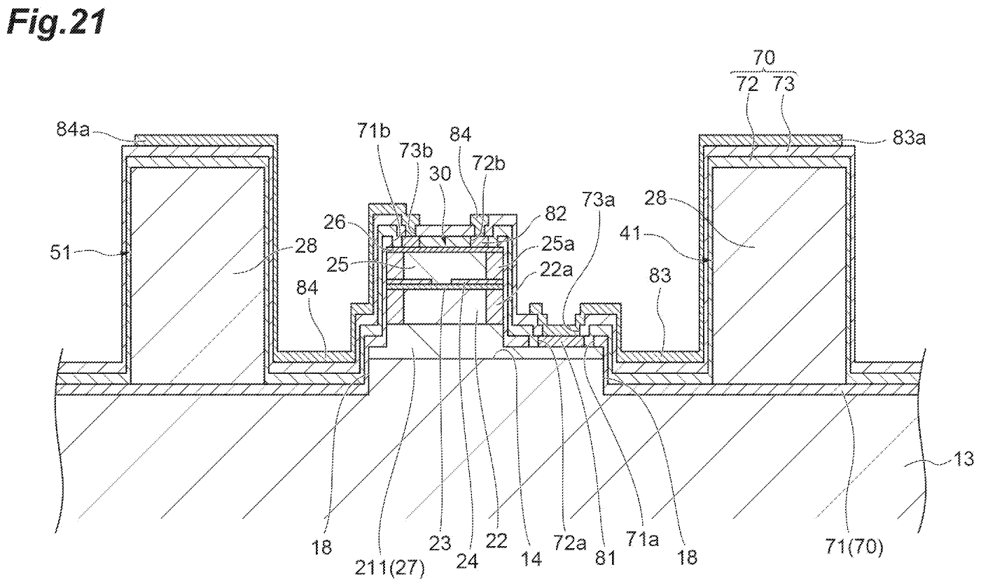

Subsequently, as illustrated in FIG. 21, third insulating film 73 is formed so as to cover second insulating film 72. Opening 73a is formed in a portion of third insulating film 73 on first electrode 81. Opening 73b is formed in a portion of third insulating film 73 on second electrode 82. Then, first conductor 83 extending from first electrode 81 to a top surface over first sub-mesa 41, and second conductor 84 extending from second electrode 82 to a top surface over second sub-mesa 51 are formed. At this time, first pad electrode 83a, second pad electrode 84a and third pad electrode 87a are formed simultaneously with first conductor 83 and second conductor 84.

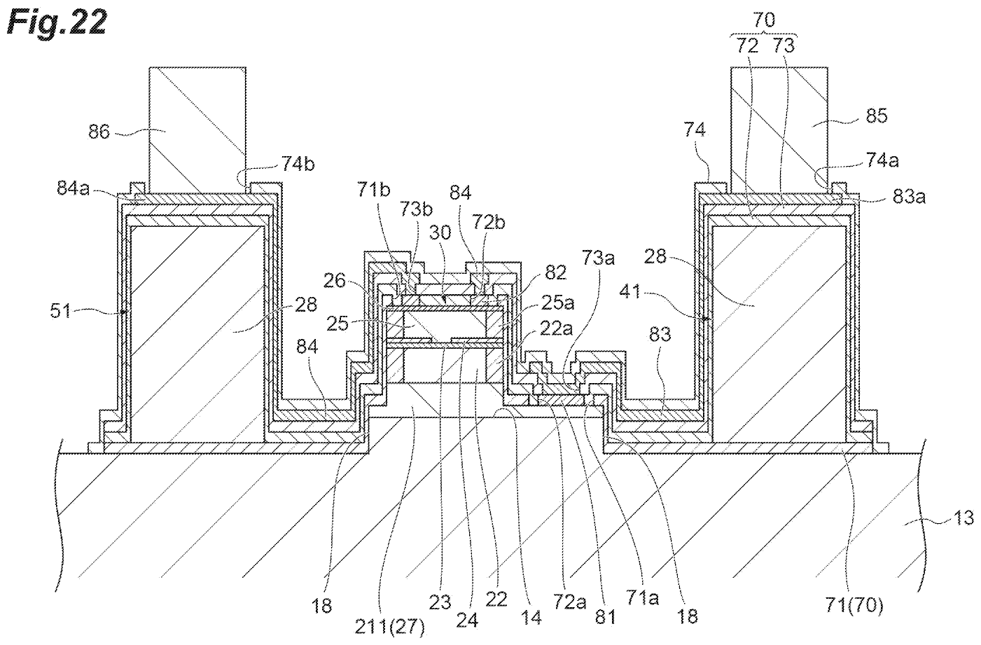

Subsequently, as illustrated in FIG. 22, insulating film 74 is formed. Opening 74a is formed in a portion of insulating film 74 that is provided on first pad electrode 83a. Opening 74b is formed on a portion of insulating film 74 that is provided on second pad electrode 84a. An opening (not shown) is formed in a portion of insulating film 74 that is provided on third pad electrode 87a. Then, first bump 85 is formed on first pad electrode 83a exposed in opening 74a. Second bump 86 is formed on second pad electrode 84a exposed in opening 74b. Third bump 88 is formed on third pad electrode 87a exposed in the opening (not shown) of insulating film 74. Finally, wafer 13 is cut into chips to form substrate 16. Through the above-described steps, semiconductor laser 1E of the present embodiment is manufactured.

Second Modification

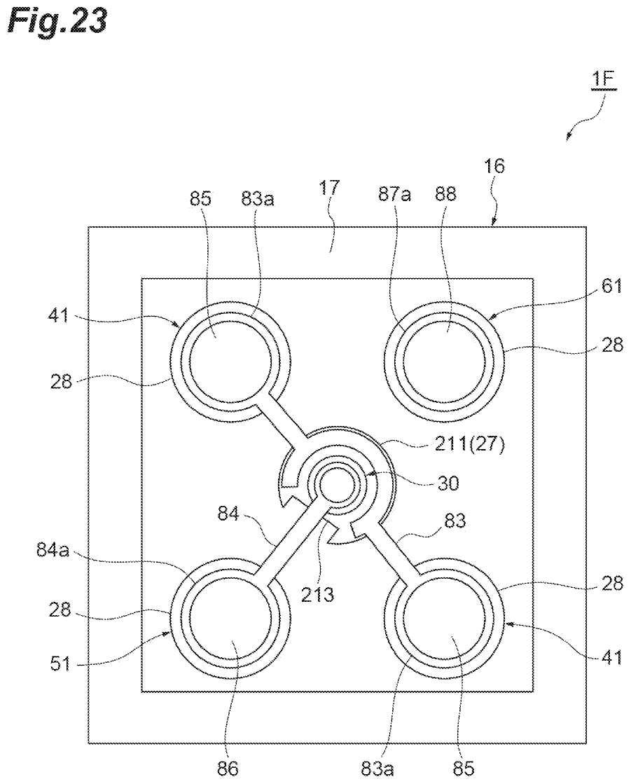

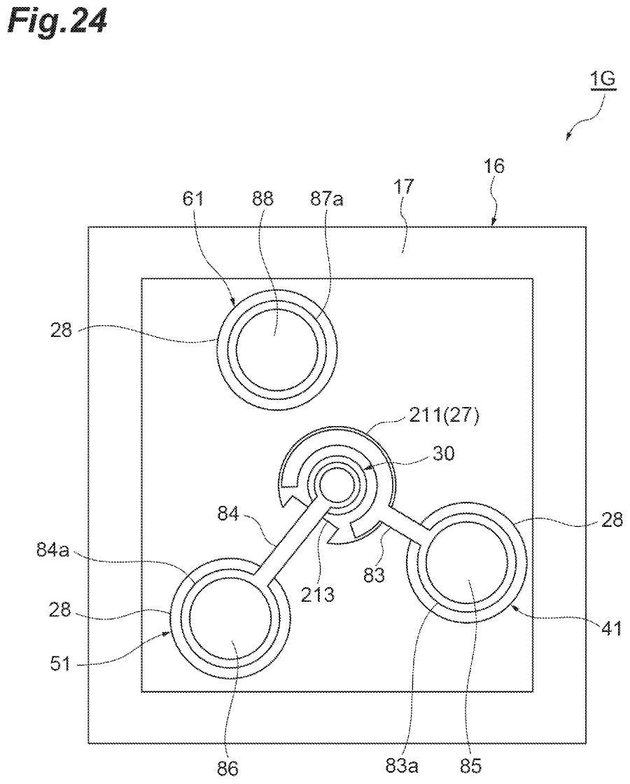

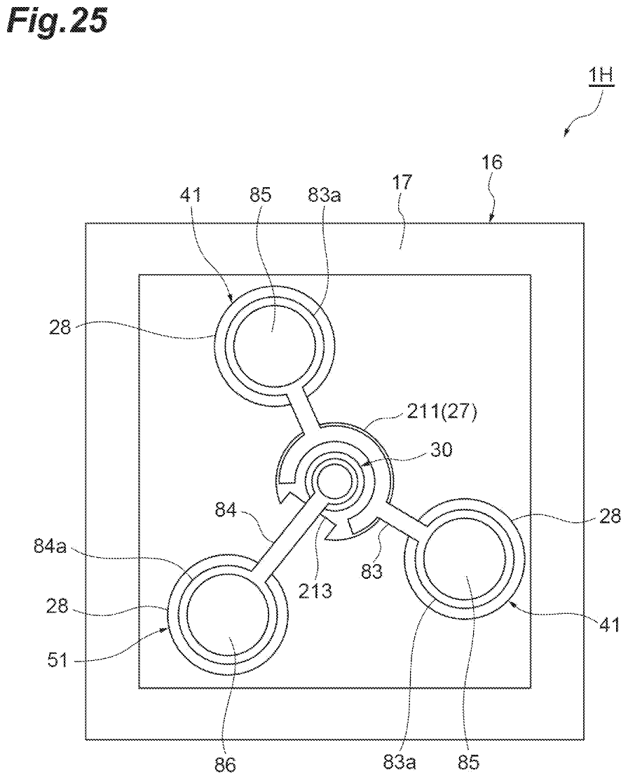

FIG. 23 is a plan view illustrating a semiconductor laser 1F according to a modification of the second embodiment. This semiconductor laser 1F is different from the second embodiment in that a plurality (two in the illustrated example) of first sub-mesas 41 are provided and that only one third sub-mesa 61 is provided. First pad electrode 83a is provided over an upper surface of each of first sub-mesas 41. First bump 85 is provided on each of first pad electrodes 83a. FIG. 24 is a plan view illustrating a semiconductor laser 1G according to another modification of the second embodiment. This semiconductor laser 1G differs from the second embodiment in that only one third sub-mesa 61 is provided. FIG. 25 is a plan view illustrating a semiconductor laser 1H according to still another modification of the second embodiment. This semiconductor laser 1H is different from the second embodiment in that a plurality (two in the illustrated example) of first sub-mesas 41 are provided and that third sub-mesa 61 is not provided. The semiconductor lasers 1F, 1G, and 1H according to the modifications illustrated in FIGS. 23, 24, and 25 can also have the same effects as the second embodiment.

Third Modification

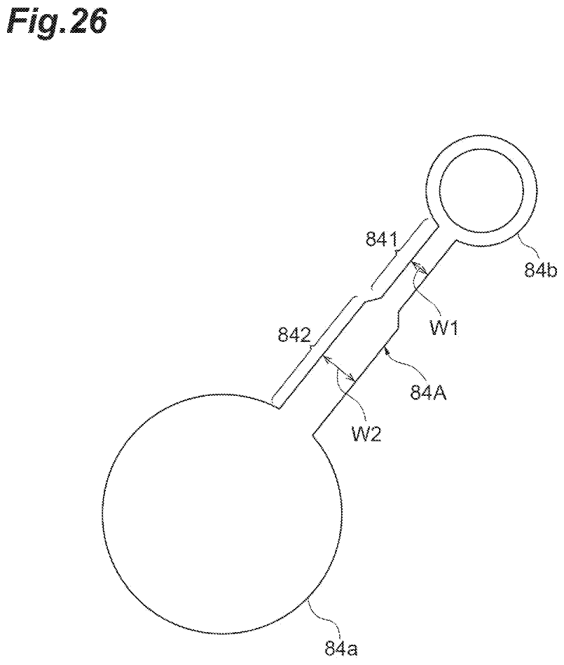

FIG. 26 is a plan view illustrating a shape of a second conductor 84A as a third modification of each of the above embodiments. The semiconductor lasers of the above embodiments and modifications may include second conductor 84A of the present modification instead of a second conductor 84.

As illustrated in FIG. 26, second conductor 84A of this modification includes a first portion 841 and a second portion 842. Second conductor 84A may include a third portion 84b on second electrode 82. First portion 841 extends from a ring-like third portion 84b on second electrode 82 to a boundary with second portion 842. Second portion 842 extends from second pad electrode 84a over second sub-mesa 50 (or 51) to the boundary with first portion 841. First portion 841 extends at least from ring-like third portion 84b on second electrode 82 to an edge of first portion 211 of n-type contact layer 21 (or 27). A width W1 of first portion 841 in a direction perpendicular to an extending direction of first portion 841 is smaller than a width W2 of second portion 842 in a direction perpendicular to an extending direction of second portion 842. In one example, width W1 is a half of width W2. In one example, width W1 is 5 μm, and width W2 is 10 μm.

As described above, at least by setting width W1 of first portion 841 extending from ring-like third portion 84b on second conductor 82 to the edge of first portion 211 to be smaller than width W2 of the other portion in second conductor 84A, a parasitic capacitance generated between second conductor 84A and n-type contact layer 21 (or 27) can be further reduced, and high frequency characteristics of the semiconductor laser can be further improved.

The surface-emitting semiconductor laser according to the present disclosure is not limited to the embodiments described above, and various modifications are possible. For example, in the first embodiment, the case where first sub-mesa 40, second sub-mesa 50, and third sub-mesa 60 have the same laminated structure as major mesa 30 is exemplified. However, at least one of first sub-mesa 40, second sub-mesa 50, or third sub-mesa 60 may have a different laminated structure from major mesa 30.

While the principles of the present invention have been illustrated and described in preferred embodiments, it will be appreciated by those skilled in the art that the invention may be modified in arrangement and detail without departing from such principles. The present invention is not limited to the specific configurations disclosed in this embodiment. Accordingly, it is claimed that all modifications and changes come from the scope of the claims and their spirit.

What is claimed is:

1. A surface-emitting semiconductor laser comprising:
a substrate having a principal surface including a first region, a second region, and a third region;
a first conductive type semiconductor layer provided on the principal surface, the first conductive type semiconductor layer including a portion on the first region and a portion on the third region being separated from each other;
a major mesa including a first semiconductor laminate, an active layer, a second semiconductor laminate, and a second conductive type semiconductor layer, the first semiconductor laminate being provided over the first region of the substrate and on the first conductive type semiconductor layer, the first semiconductor laminate serving as a distributed Bragg reflector, the active layer being provided on the first semiconductor laminate, the second semiconductor laminate being provided on the active layer, the second semiconductor laminate serving as a distributed Bragg reflector, the second conductive type semiconductor layer being provided on the second semiconductor laminate;
a first sub-mesa provided over the second region of the substrate and on the first conductive type semiconductor layer;
a second sub-mesa provided over the third region of the substrate and on the first conductive type semiconductor layer;
an insulating film having a first opening and a second opening, the insulating film being provided on a side surface and an upper surface of each of the major mesa, the first sub-mesa, and the second sub-mesa, the first opening being provided over the first conductive type semiconductor layer connected to the major mesa, the second opening being provided over the second conductive type semiconductor layer of the major mesa;
a first electrode being in contact with the first conductive type semiconductor layer through the first opening of the insulating film;
a second electrode being in contact with the second conductive type semiconductor layer through the second opening of the insulating film;
a first conductor including a first pad electrode provided over the first sub-mesa and on the insulating film, the first conductor being electrically connected to the first electrode;
a second conductor including a second pad electrode provided over the second sub-mesa and on the insulating film, the second conductor extending on the insulating film along each side surface of the second sub-mesa and the major mesa to reach the second electrode;
a first bump provided on the first pad electrode; and
a second bump provided on the second pad electrode.

2. The surface-emitting semiconductor laser according to claim 1, wherein each of the first sub-mesa and the second sub-mesa has a laminated structure same as a laminated structure of the major mesa.

3. The surface-emitting semiconductor laser according to claim 1, further comprising a recess extending through the first conductive type semiconductor layer to reach the substrate,
wherein the portion on the first region and the portion on the third region in the first conductive type semiconductor layer are separated from each other by the recess.

4. The surface-emitting semiconductor laser according to claim 3, wherein the recess extends along an outer edge of the first region so as to surround the first region.

5. The surface-emitting semiconductor laser according to claim 1, wherein the principal surface of the substrate further includes a fourth region, and
wherein the surface-emitting semiconductor laser further comprises:
a third sub-mesa provided over the fourth region of the substrate and on the first conductive type semiconductor layer; and
a third bump provided over the third sub-mesa, the third bump being insulated from both of the first conductor and the second conductor.

6. The surface-emitting semiconductor laser according to claim 1, wherein each of the first bump and the second bump contains gold.

7. The surface-emitting semiconductor laser according to claim 1, wherein the second conductor includes a first portion, a second portion and a third portion, the third portion being on the second electrode, the first portion extending from the third portion to the second portion, the second portion extending from the second pad electrode to the first portion, wherein a width of the first portion is smaller than a width of the second portion.

8. A surface-emitting semiconductor laser comprising:
a substrate having a principal surface including a first region, a second region, and a third region;
a first conductive type semiconductor layer provided on a region including at least the first region among other regions excluding the third region in the principal surface;
a major mesa including a first semiconductor laminate, an active layer, a second semiconductor laminate, and a second conductive type semiconductor layer, the first semiconductor laminate being provided over the first region of the substrate and on the first conductive type semiconductor layer, the first semiconductor laminate serving as a distributed Bragg reflector, the active layer being provided on the first semiconductor laminate, the second semiconductor laminate being provided on the active layer, the second semiconductor laminate serving as a distributed Bragg reflector, the second conductive type semiconductor layer being provided on the second semiconductor laminate;
a first sub-mesa including a dielectric, the first sub-mesa being provided over the second region of the substrate;
a second sub-mesa including a dielectric, the second sub-mesa being provided over the third region of the substrate;
an insulating film having a first opening and a second opening, the insulating film being provided on at least an upper surface and a side surface of the major mesa, the first opening being provided over the first conductive type semiconductor layer, the second opening being provided over the second conductive type semiconductor layer;
a first electrode being contact with the first conductive type semiconductor layer through the first opening of the insulating film;
a second electrode being contact with the second conductive type semiconductor layer through the second opening of the insulating film;
a first conductor including a first pad electrode provided over the first sub-mesa, the first conductor being electrically connected to the first electrode;
a second conductor including a second pad electrode provided over the second sub-mesa, the second conductor extending along a side surface of the second sub-mesa, the second conductor extending on the insulating film along a side surface of the major mesa to reach the second electrode;
a first bump provided on the first pad electrode; and
a second bump provided on the second pad electrode.

9. The surface-emitting semiconductor laser according to claim 8, wherein the dielectric of the first sub-mesa and the dielectric of the second sub-mesa include polyimide.

10. The surface-emitting semiconductor laser according to claim 8, wherein the principal surface of the substrate further includes a fourth region, and
wherein the surface-emitting semiconductor laser further comprises:
a third sub-mesa including a dielectric, the third sub-mesa being provided over the fourth region of the substrate; and
a third bump provided over the third sub-mesa, the third bump being insulated from both of the first conductor and the second conductor.

11. The surface-emitting semiconductor laser according to claim 8, wherein a step is formed on the principal surface, due to the step, a level of a region other than the first region in the principal surface is lower than a level of first region.

12. The surface-emitting semiconductor laser according to claim 8, wherein levels of upper surfaces of the first sub-mesa and the second sub-mesa are higher than a level of the first region.

13. The surface-emitting semiconductor laser according to claim 8, wherein each of the first bump and the second bump contains gold.

14. The surface-emitting semiconductor laser according to claim 8, wherein the second conductor includes a first portion, a second portion and a third portion, the third portion being on the second electrode, the first portion extending from the third portion to the second portion, the second portion extending from the second pad electrode to the first portion, wherein a width of the first portion is smaller than a width of the second portion.
